(19) United States
(12) Patent Application Publication
(10) Pub. No.: US 2025/0386656 A1
(43) Pub. Date: Dec. 18, 2025

(54) Aerosol Spray Jet Printable Ink Compositions for Redox Gating Materials and Semiconducting Channel Materials

(71) Applicant: UCHICAGO ARGONNE, LLC, Chicago, IL (US)

(72) Inventors: Wei Chen, Naperville, IL (US); Yuepeng Zhang, Naperville, IL (US); Andrew Erwin, La Grange, IL (US); Shiyu Hu, Willowbrook, IL (US)

(21) Appl. No.: 18/747,338

(22) Filed: Jun. 18, 2024

(51) Int. Cl. H10K 10/46; C09D 11/322; C09D 11/36

(52) U.S. Cl. CPC H10K 10/488; C09D 11/322; C09D 11/36; H10K 10/478

(57) ABSTRACT

Electronic devices printed using aerosol spray jet printable inks for forming redox gating materials and/or inks for forming semiconducting channels with semiconducting nanoparticles are disclosed herein.

### STATEMENT OF GOVERNMENT SUPPORT

This invention was made with government support under Contract No. DE-AC02-06CH11357 awarded by the United States Department of Energy to UChicago Argonne, LLC, operator of Argonne National Laboratory. The government has certain rights in the invention.

### FIELD

The disclosure relates to aerosol spray printable ink compositions for a redox gating material and methods of forming redox gating materials suing aerosol spray printing.

### BACKGROUND

Printed hybrid electronics (PHE) is an emerging manufacturing platform that allows for the production of flexible and portable microelectronics. Aerosol jet printing enables the creation of 3D electronic circuits. However, the lack of appropriate functional inks has hindered the widespread adoption of printing techniques in microelectronics. Current inks have limitations in terms of processing steps, stability, and gating methods, which restrict their scalability and application in important components like CMOS inverters.

### SUMMARY

The inks of the disclosure advantageously provide formulations for aerosol jet printing. The inks of the disclosure can provide for the creation of flexible semiconducting nanocomposite films with redox-gating capabilities. The inks of the disclosure can provide for complex CMOS circuits to be developed with adjustable low-power gating voltage in a three-dimensional format within the PHE framework. For example, the CMOS circuits can have sub-volt gating voltages.

An aerosol spray printable ink composition for printing a redox gating material in accordance with the disclosure can include one or more redox agents, the one or more redox agents comprising a transition metal salt with variable valency and/or a polymer with at least one redox-active functional group; and a solvent system comprising, based on the total weight of the solvent system, about 85 wt % to 95 wt % of a low boiling point solvent and about 5 wt % to about 15 wt % of a high boiling point solvent, wherein the low boiling point solvent has a boiling point below about 100° C. and the high boiling point solvent has a boiling point above about 125° C. The redox agent is present in the composition in an amount of about 3 wt % to about 10 wt % based on the total weight of the ink composition.

A semiconducting aerosol spray printable ink composition for printing a channel material in accordance with the disclosure can include semiconducting nanoparticles present in an amount up to about 20 wt %, the semiconducting nanoparticles having an average particle size of 100 nm or less; a solvent system comprising, based on the total weight of the solvent system, about 85 wt % to 95 wt % of a low boiling point solvent and about 5 wt % to about 15 wt % of a high boiling point solvent, wherein the low boiling point solvent has a boiling point below about 100° C. and the high boiling point solvent has a boiling point above about 125° C.; a stabilizing polymer present in an amount of at least about 5 wt % based on the weight of the nanoparticles, the stabilizing polymer being dissolvable in the solvent; and a crosslinker.

A method of aerosol spray printing an electronic device in accordance with the disclosure can include depositing a semiconducting ink composition onto a substrate comprising electrodes between the electrodes, the semiconducting ink composition being deposited by aerosol spray printing, crosslinking the deposited semiconducting ink composition to form the semiconducting channel; and depositing a redox gating material ink composition onto the semiconducting channel by aerosol spray printing. The semiconducting ink composition can include semiconducting nanoparticles present in an amount up to about 20 wt %, the semiconducting nanoparticles having an average particle size of 100 nm or less, a solvent system comprising, based on the total weight of the solvent system, about 85 wt % to 95 wt % of a low boiling point solvent and about 5 wt % to about 15 wt % of a high boiling point solvent, wherein the low boiling point solvent has a boiling point below about 100° C. and the high boiling point solvent has a boiling point above about 125° C., a stabilizing polymer present in an amount of at least about 5 wt % based on the weight of the nanoparticles, the stabilizing polymer being dissolvable in the solvent; and a crosslinker. The redox gating material ink composition can include one or more redox agents, the one or more redox agents comprising a transition metal salt with variable valency and/or a polymer with at least one redox-active functional group; and a solvent system comprising, based on the total weight of the solvent system, about 85 wt % to 95 wt % of a low boiling point solvent and about 5 wt % to about 15 wt % of a high boiling point solvent, wherein the low boiling point solvent has a boiling point below about 100° C. and the high boiling point solvent has a boiling point above about 125° C. The redox agent can be present in the composition in an amount of about 3 wt % to about 10 wt % based on the total weight of the ink composition.

### BRIEF DESCRIPTION OF THE DRAWINGS

FIG. 1 is a schematic illustration of aerosol spray jet printing of a redox-gating material and channel material in accordance with the disclosure.

FIG. 2 is a schematic of redox-active components and their oxidation/reduction reactions of a redox gating material ink in accordance with the disclosure.

FIG. 3A is an optical microscopy image of a redox gating ink in accordance with the disclosure, containing potassium ferrocyanide (PFC) as the redox active agent and polyvinyl alcohol (PVOH or PVA) as a film forming agent, spin-coated into a silicon substrate.

FIG. 3B is an AFM image of redox gating ink spin-coated into a silicon substrate.

FIG. 3C is an optical micrograph of a redox gating ink printed via aerosol spray het onto a silicon substrate.

FIG. 3D is a cyclic voltammetry (CV) scan of the aerosol spray jet printed redox gating ink film at different scan rates.

FIG. 4 is a schematic of components of a channel material ink in accordance with the disclosure.

FIG. 5A is a photograph of a channel material ink for aerosol spray jet printing in accordance with the disclosure.

FIG. 5B is a graph showing the size distribution of nanoparticle aggregates with and without SMA stabilizer and processed using different milling conditions.

FIG. 5C is a graph showing the size distribution of nanoparticle aggregates at different weight percentages of VO₂, demonstrating that the VO₂ content can be varied without substantially influencing the size distribution of aggregates. Weight percent of PSMA was held constant at 0.5%.

FIG. 5D is a schematic illustrating the solution assembly of polymer-adsorbed metal oxide nanoparticles into limited aggregates.

FIG. 6A is a flow curve showing the viscosity of SMA-stabilized nanoparticles in EtOH/terpineol inks with different VO₂ loading fractions.

FIG. 6B is a flow curve showing the viscosity of Gum Arabic-stabilized nanoparticles in H₂O/glycerol inks with different VO₂ loading fractions.

FIG. 7A includes optical microscope images showing the effect of crosslinker concentration on the microscale morphology of thermally crosslinked deposited polyethyleneimine (PEI)+VO₂ inks.

FIG. 7B includes AFM images showing the effect of crosslinker concentration on the microscale and nanoscale morphology of thermally crosslinked deposited PEI+VO₂ inks.

FIG. 7C includes photographs of the thermally crosslinked inks that are deposited into free-standing films, both with and without including VO₂ nanoparticles.

FIG. 7D includes optical microscope images (left) and SEM images (right) which demonstrate how thermally crosslinking AEROSOL SPRAY JET PRINTING-printed films can prevent the occurrence of microscale cracks.

FIG. 7E is a graph showing the I-V characteristics of an uncrosslinked PEI+VO₂ film. The presence of microscale cracks results in an insulating film.

FIG. 7F is a graph showing the I-V characteristics of a crosslinked PEI+VO₂ film. Using thermal crosslink to prevent microscale cracking results in a measurable conductivity.

FIG. 8A includes SEM images of several AEROSOL SPRAY JET PRINTING-printed nanocomposite films subjected to rapid photo annealing (RPA) at the different indicated photonic energy densities.

FIG. 8B is a graph showing the corresponding I-V characteristics of the aerosol spray jet printing-printed films treated by RPA at different photonic energy densities.

FIG. 8C is a graph showing the temperature dependence of the electrical resistance of several aerosol spray jet printing-printed films treated by RPA at different photonic energy densities.

FIG. 8D provides the XRD curves of several aerosol spray jet printing-printed films treated by RPA at different photonic energy densities.

FIG. 9A is a DSC thermogram demonstrating the metal-to-insulator transition corresponding to the dispersed VO₂ phase in the solid PEI+VO₂ nanocomposite channel. The transition disappears when heated above 110° C. in air due to oxidation.

FIG. 9B is a TGA curve showing the onset of thermal decomposition occurring around 200° C. in an inert nitrogen atmosphere.

FIG. 10 includes optical microscope images of aerosol spray jet printed ink composition in accordance with the disclosure showing the change in resolution as a function of sheath: aerosol gas flow.

FIG. 11A is a graph comparing DSC thermograms (2^{nd} heating, 10° C./min in nitrogen) of the several dried nanocomposite inks formed by the different indicated processing routes, with and without the stabilizing SMA.

FIG. 11B is the TGA curves (heating 10° C./min in nitrogen) for SMA-stabilized nanocomposite inks formed from colloidal milling in EtOH with different nominal VO₂ loading fractions.

FIG. 11C is a graph comparing the corresponding conductivities (determined by impedance spectroscopy) of the samples in FIG. 11B as a function of temperature. Note that the sample with 15% VO₂ could not form a film robust enough sample for impedance spectroscopy due to brittle cracking of the film. The results are compared to a control sample that includes only the crosslinked SMA (no VO₂ present). Dashed lines show a linear fit to the insulating phase of VO₂, from which an electronic bandgap of ˜0.6 eV can be calculated. This value is the same as that anticipated for pristine VO₂.

FIG. 12A includes AFM images of the spin-coated films of milled VO₂ nanoparticles with no included polymer stabilizer. The topographic height profile corresponds to the double-headed arrow in the AFM image, which shows how the individual nanoparticles are under well under 100 nm in size.

FIG. 12B includes AFM images of the spin-coated films of milled VO₂ nanoparticles with different nanoparticle loading fractions in the presence of SMA stabilizer.

FIG. 13A includes optical and SEM images of AEROSOL SPRAY JET PRINTING-printed line patterns on a silicon wafer revealing the interconnected nanoparticle morphology. The printed line width is 100 μm and can be further adjusted by adjusting printing parameters.

FIG. 13B is a cross-sectional schematic outlining the layout of various printed transistor components with electrical connections.

FIG. 13C provides top-down view photographs that show the step-by-step printing process of the device.

FIG. 14A shows a top-down optical image and a schematic of the printed redox gating material with electrodes with the corresponding two-terminal I-V curves for the redox gating material.

FIG. 14B shows a top-down optical image and a schematic of the printed VO₂ transistor with the corresponding two-terminal I-V curves for the VO₂/redox stack.

FIG. 15A contains the transfer characteristic curve of the transistor with a V_{gs} sweep rate of 500 mV/s.

FIG. 15B is the time response of las of the transistor upon application of a gate voltage V_{gs}=±0.4 V and a switching delay of 19 s.

FIG. 15C shows the gate voltage cycling measurement of the transistor with the cyclic application of V_{gs}=±0.4 V and a switching delay of 5 s.

### DETAILED DESCRIPTION

The aerosol spray printable ink composition for a redox gating material in accordance with the disclosure includes one or more redox agents and a solvent system comprising a low boiling point solvent and a high boiling point solvent. The solvent system includes the low boiling point solvent present in an amount of about 85 wt % to 95 wt % based on the total weight of the solvent system and the high boiling point solvent present in an amount of about 5 wt % to about 15 wt % based on the total weight of the solvent system. The redox agent is present in the ink composition in an amount of about 3 wt % to about 10 wt % based on the total weight of ink composition. The ink compositions in accordance with the disclosure can be formulated for printing a solid state redox gating material or a liquid state redox gating material. For solids state redox gating materials, the ink composition can further include a film former and a gelation agent. For example, the film former can be provided in the form of crosslinkable functional groups present on the polymer having one or more redox functional groups and the gelation agent, such as a crosslinker, can be further included in the formulation. Alternatively, or additionally, a separate polymer film forming agent and gelation agent can be included in the formulation.

The aerosol spray printable ink composition for printing a semiconducting channel in accordance with the disclosure can include semiconducting nanoparticles, a solvent system, a stabilizing polymer, and a crosslinker. The nanoparticles are present in the composition in an amount of at least about 5 wt % based on the total weight of the ink composition. The particles can have an average particle size of less than 100 nm. The stabilizing polymer is a polymer having organic functional groups and is crosslinkable by the crosslinker. The stabilizing polymer and solvent are selected such that the stabilizing polymer is soluble in the solvent. The composition can include the stabilizing polymer in an amount of about 5 wt % to about 60 wt % based on the total weight of the nanoparticles. The solvent system includes the low boiling point solvent present in an amount of about 85 wt % to 95 wt % based on the total weight of the solvent system and the high boiling point solvent present in an amount of about 5 wt % to about 15 wt % based on the total weight of the solvent system.

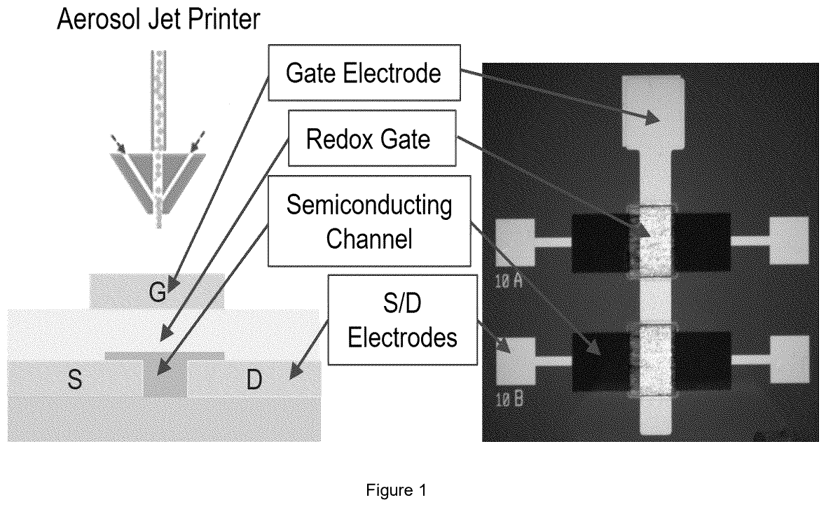

Referring to FIG. 1, the ink compositions of the disclosure can be aerosol spray jet printed to form a redox gate and semiconducting channel of an electronic device.

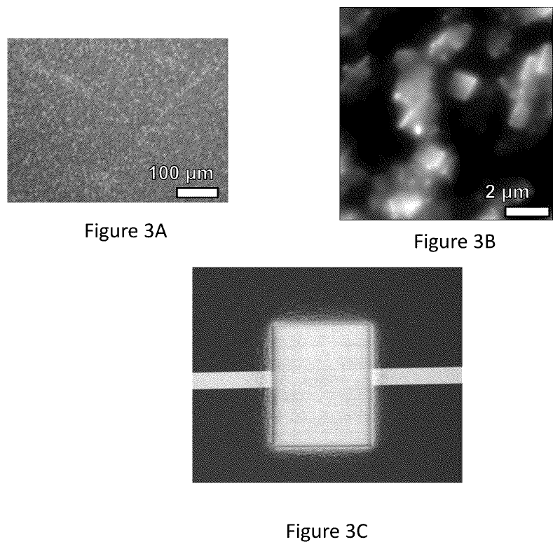

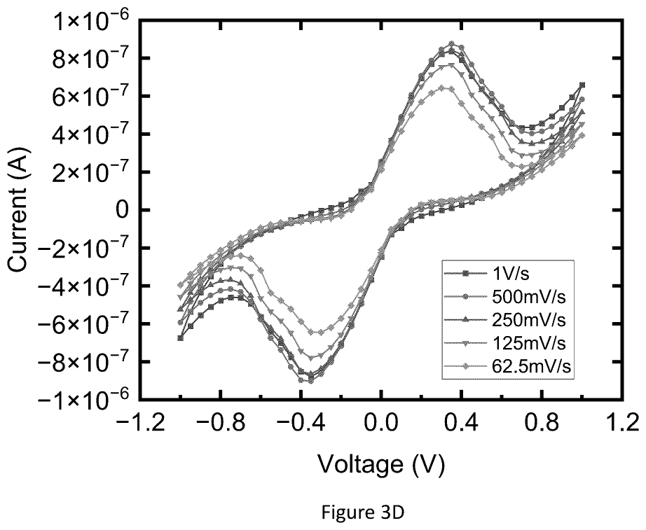

The redox gating materials formed by the inks and methods of the disclosure can be used with a variety of channel materials, including, but not limited to, functional metal oxides and low-dimensional materials. For example, functional metal oxides can include one or more of WO₃, VO₂, LaNiO₃, NdNiO₃, Nd₁₋ₓSrₓNiO₂, and Pr₁₋ₓSrₓNiO₂. Low-dimensional materials can include, for example, one or more of Bismuth, MoS₂, HfS₂, and WSe₂. Redox gating materials of the disclosure exhibit a standard redox potential of −1V-1V (FIG. 3D). The redox gating materials printed using the inks and methods of the disclosure can be electron-injecting or hole-injecting.

### Redox Gating Material Ink Compositions

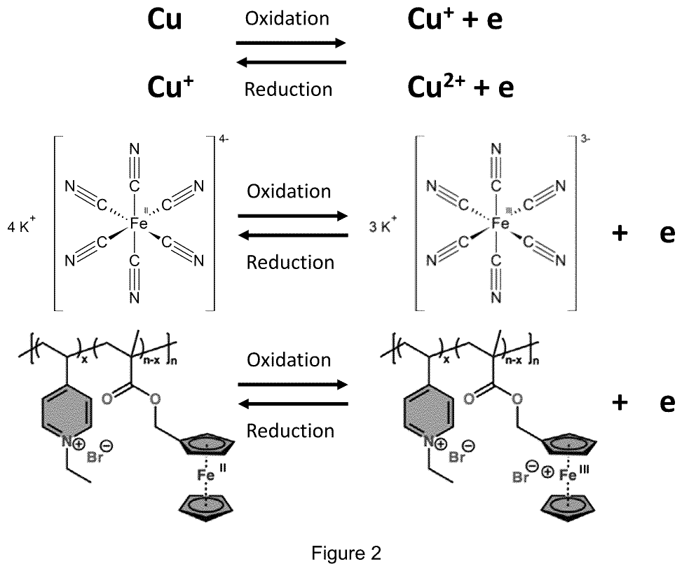

Inks in accordance with the disclosure can be useful for printing redox gating materials by aerosol spray jet printing methods. The printed redox gating material can be in a solid (such s as a gel) state material or can remain in a liquid state. In general, the inks include a redox gating agent and a solvent system. FIG. 2 is a schematic showing examples of redox-active components and their oxidation/reduction reactions in the redox gating material ink.

The redox gating agent can include one or more transition metal salts with variable valency and/or a polymer having at least one redox functional group. For example, the redox functional group can be provided as a repeat unit of the polymer.

The redox active agent can be included in an amount of about 3 wt % to about 10 wt %, about 5 wt % to about 8 wt %, or about 4 wt % to about 9 wt % based on the total weight of the ink composition. Other suitable amounts include, based on the total weight of the ink composition, about 3, 4, 5, 6, 7, 8, 9, or 10 wt % or any values therebetween or ranges defined by the values.

Redox gating agents provided as transition metal salts with variable valency can include one or more of Cu ions, Fe ions, V ions, Co ions, Ni ions, and their corresponding coordination ions. The metal salt could be present in an amount below the saturated concentration in electrolyte solutions.

Redox gating agents provided as a polymer having at least one redox active functional group can include the redox functional group as a repeat unit of the polymer, grafted to the backbone of the polymer, or otherwise embedded in the polymer. The redox agent can include about 5% to about 85% by mole of the redox-active functional groups based on the total mole of the redox gating material. Any of the polymers used in the inks of the disclosure, including poly(ionic) liquids) can optionally include, in addition to the redox active functional group, one or more crosslinkable functional groups and provide a film forming capability when the ink further includes a gelation agent to crosslink the polymer and thereby provide a solid state redox gating material.

The redox active functional group can be one or more of ferrocene, viologen, quinone, TEMPO, thiophene, benzophenone, ferrocyanide, and ferricyanide.

The redox agent can be provided as a poly(ionic) liquid, for example. Poly(ionic liquids) (PILs), are polymers having redox-active functional groups and ionic liquid species in monomer repeating units, connected through a polymeric backbone to form a macromolecular architecture. The redox-active functional groups can include for example, ferrocene, viologen, quinone, TEMPO, thiophene, benzophenone, ferrocyanide, ferricyanide, and combinations thereof. The ionic liquid species can include one or more of quaternary imidazolines, imidazoliums, quaternary pyridines, ferrocenium, cobaltocenium, ferrocyanide, ferrocyanide, dicyanamide, bis(trifluoromethylsulfonyl)imide, and hexafluorophosphate, and combinations.

The PILs can include conjugated PILs or metal-containing PILs.

The conjugated PIL can include polythiophene PIL, poly(quinone) PIL, poly(viologen) PIL, and combinations thereof. For example, polythiophene PIL can include one or more of 3,4-ethylenedioxythiophene, imidazole-functionalized thiophene monomers, and combinations. Poly(quinone) PIL can include one or more of repeating quinone isomers, including benzoquinones, naphthoquinones, anthraquinone, phenanthraquinones, and combinations. poly(viologen) PIL can include one or more of conjugated bi-/multi-pyridyl groups, 1,1′-disubstituted-4,4′-bipyridiliums, and combinations.

The metal-containing PIL can include one or more of ferrocene-containing poly(ionic liquids), ferrocyanide-containing poly(ionic liquids), ferricyanide-containing poly(ionic liquids), and combinations. For example, ferrocene-containing poly(ionic liquids) can include one or more of ferrocenylenes, ferrocenylsilanes, pendant ferrocenes, and combinations.

The solvent system includes a high boiling point solvent and a low boiling point solvent. High boiling point solvents have a boiling point of at least about 125° C., and low boiling point solvents have a boiling point of 100° C. or less. The high boiling point solvent can include, for example, one or more of glycerol, terpineol, ethylene glycol, diethylene glycol, propylene glycol, N-methylpyrrolidone (NMP), dimethyl sulfoxide (DMSO), xylene, p-cymene, isophorone, cyrene, menthol, menthanol, eucalyptol, and ethylene carbonate (EC). The low boiling point solvent can include, for example, one or more of water, tetrahydrofuran, ethanol, methyl ethyl ketone (MEK), acetone, methyl isobutyl ketone (MIBK), diethyl ketone, cyclohexane, n-butyl acetate, and ethyl lactate. Commercially available low boiling point solvents can include VertecBio™ ELSOL® KTR1, VertecBio™ ELSOL® KTR2, and VertecBio™ EL, and can be used alone, in combination with any of the low boiling point solvents identified herein. For example, the solvent system can include water and glycerol.

The solvent system can include about 85 wt % to about 95 wt %, about 85 wt % to about 90 wt %, about 87 wt % to about 93 wt %, or about 90 wt % to about 95 wt % of the low boiling point solvent based on the total weight of the solvent system. Other suitable amounts include, based on the total weight of the solvent system, for example, about 85, 86, 87, 88, 89, 90, 91, 92, 93, 94, or 95 wt %, or any value therebetween or ranges defined by the values.

The solvent system can include about 5 wt % to about 15 wt %, about 10 wt % to about 14 wt %, about 7 wt % to about 11 wt %, or about 5 wt % to about 10 wt %, of the high boiling point solvent based on the total weight of the solvent system. Other suitable amounts include, based on the total weight of the solvent system, for example, about 5, 6, 7, 8, 9, 10, 11, 12, 13, 14, or 15 wt %, or any values therebetween or any ranges defined by the values.

The ink composition can include one or more additional components, including, but not limited to gelation agents (e.g., crosslinkers), film formers, viscosity modifying agents, and electrolytes. In various ink compositions of the disclosure, components can have dual or even multi-functionality. For example, the redox gating agent can additionally serve as an electrolyte. For example, ferrocyanide salt is both a redox active agent and an electrolyte. In such inks, additional electrolyte can optionally be further included. When the redox gating agent is provided as a polymer having a redox functional group, the polymer can have one or more crosslinkable groups and to further provide film forming functionality. The polymer can also or alternatively provide viscosity modifying properties. In either case, additional film formers and/or viscosity modifying agents can be optionally included.

The inclusion of an electrolyte in the ink composition can aid in balancing space charge accumulation in the printed redox gating material, thereby allowing for faster switching and promoting reversibility. The electrolyte can be, for example, an ionic liquid. Examples of electrolytes that can be included in the ink compositions of the disclosure include one or more of 1-ethyl-3-methylimidazolium dicyanamide (EMIM-DCA), DEME-TFSI, EMIM-TFSI, and 1-Butyl-3-methylimidazolium dicyanamide (BMIM-DCA). The electrolyte as an additional, separate component, can be included in an amount of 0 wt % to 99 wt %. The redox gating agent may serve as an electrolyte and ink compositions having electrolytic redox gating agents can be free of added electrolyte or can include an additional, added electrolyte.

The addition of film formers (or the presence of such functionality in a component of the ink composition) and gelation agents can provide for a solid state redox gating material to be printed. The film former can be provided by the polymer having the redox functional group or as a separate component. For example, the film former can be PVOH. The polymer having the redox functional group can include PVOH or other crosslinkable groups.

For forming the solid state redox gating material, the ink can further include a gelation agent for crosslinking the polymer or other film former. The gelation agent can be one or more of polyols, polyethylene glycol (PEG), Polypropylene glycol (PPG), Poloxamer PEO-PPO-PEO, Polyetheramines, di-polyamines, tri-polyamines, multi-functional epoxies multifunctional bis[2-(methacryloyloxy)ethyl]phosphate (b2mp), PEG diacrylates, PEG dimethacrylates, multifunctional acrylates, and multifunctional methacrylates, multifunctional cyclic carbonates, and triethanolamine. polyethylene glycol, bis[2-methacryloyloxy)ethyl]phosphate, glyoxal. Commercially available crosslinkers include, for example, JEFFAMINE® Polyetheramines, multi-functional epoxies (e.g., Nagase DENACOL™. Selection of a suitable crosslinker for a selected stabilizing polymer can be made by the skilled person based on knowledge in the art. For example, the crosslinker for crosslinking poly(styrene-co-maleic anhydride) (SMA) can be polyols, polyethylene glycol (PEG), Polypropylene glycol (PPG), Poloxamer PEO-PPO-PEO, Polyetheramines, di-polyamines, tri-polyamines, multi-functional epoxies (Nagase DENACOL™). Crosslinkers for polyethyleneimine (PEI) can include one or more of bis[2-(methacryloyloxy)ethyl] phosphate (b2mp), PEG diacrylates, PEG dimethacrylates, multifunctional acrylates, multifunctional methacrylates, Nagase VEEA and VEEM, and multifunctional cyclic carbonates. Any of the foregoing can be included as the crosslinking agent for crosslinking one or more crosslinkable groups present on the film former or the polymer having the redox functional group.

The ink composition for the redox gating material can be aerosol spray jet printed on to a substrate, for example, over or under a channel material, as a flexible film that has reversible redox behavior. The ink compositions and printing thereof are not restricted by transistor geometry.

### Semiconducting Nanoparticle Composite Channel Material Ink Composition

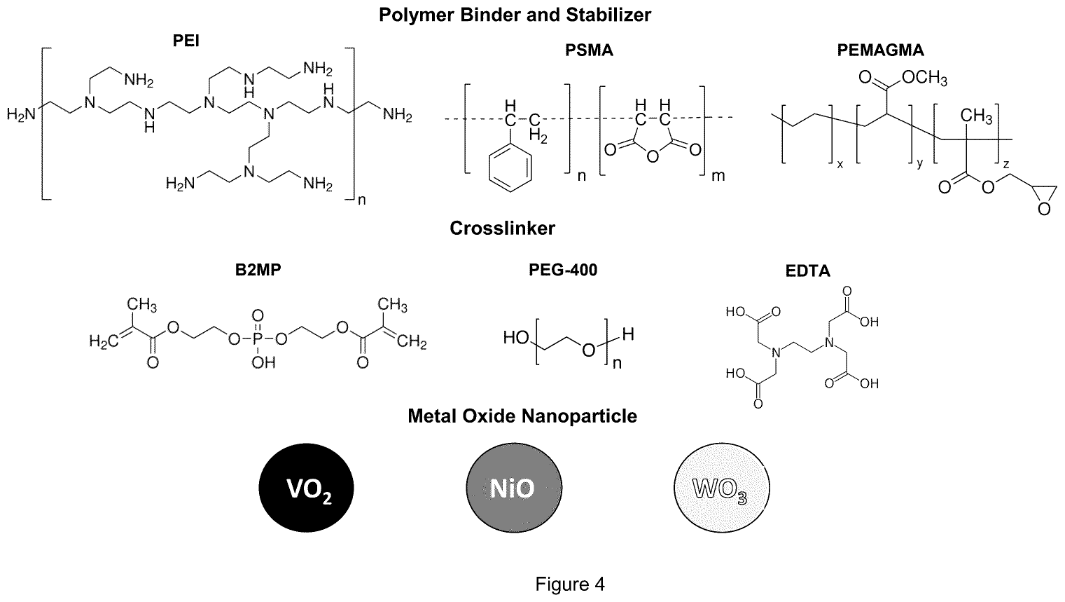

The aerosol spray printable ink composition for printing a semiconducting channel in accordance with the disclosure can include semiconducting nanoparticles, a solvent system, a stabilizing polymer, and a crosslinker. The nanoparticles are present in the composition in an amount of at least about 5 wt % based on the total weight of the ink composition. The particles can have an average particle size of less than 100 nm. FIG. 4 is a schematic of components of a semiconducting ink in accordance with the disclosure, showing examples for the nanoparticle, stabilizing polymer, and crosslinker.

The semiconducting nanoparticles can have an average particle size of about 5 nm to about 100 nm, about 10 nm to about 50 nm, about 20 nm to about 100 nm, about 40 nm to about 60 nm, about 30 nm to about 80 nm, about 70 nm to about 100 nm. Other suitable average particle sizes include about 5, 10, 15, 20, 25, 30, 35, 40, 45, 50, 55, 60, 65, 70, 75, 80, 85, 90, 95, or 100 nm, or any values therebetween or ranges defined by such values (FIG. 12A).

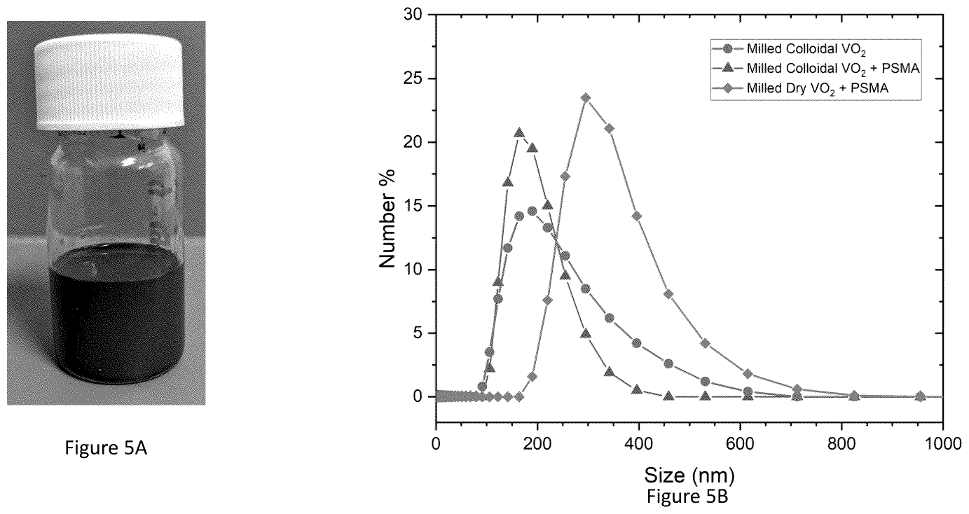

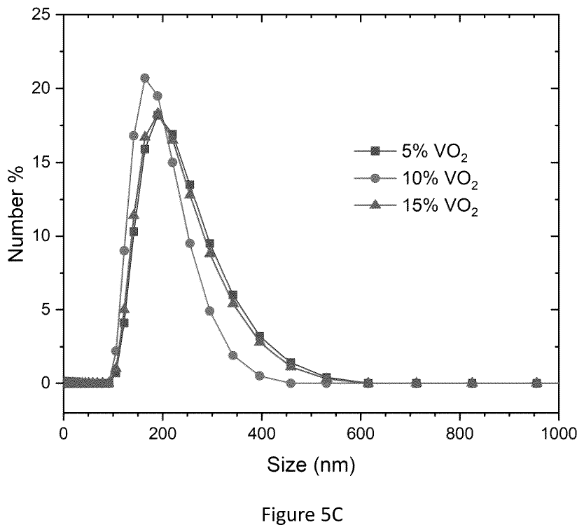

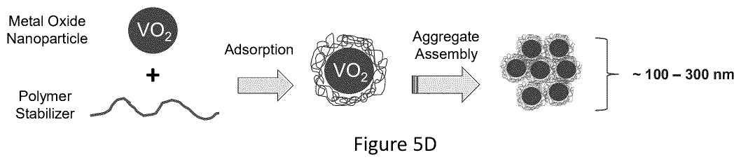

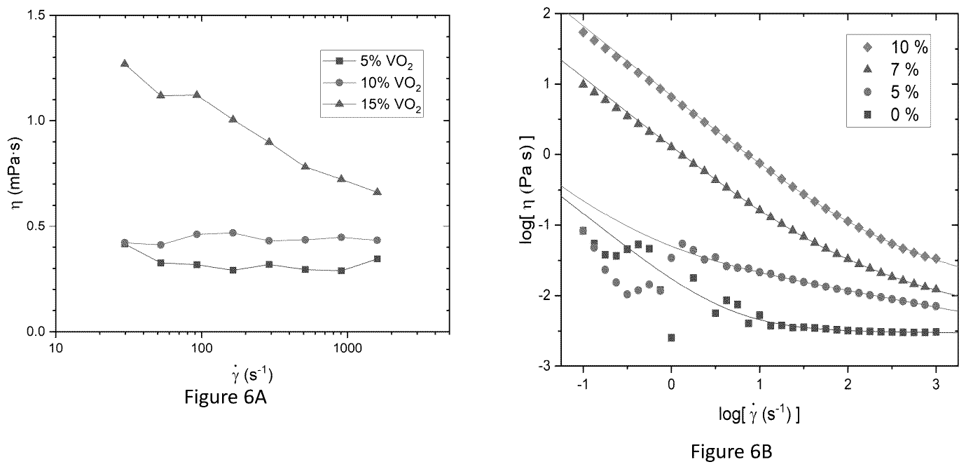

Desired nanoparticle sizes can be achieved using any suitable milling processes. For example, nanoparticles can be dry or colloidally milled to reduce the particle aggregate size. Subsequently, they can be sonicated to break up any aggregates or clusters that form to keep the particle size distribution low (FIG. 5). It was observed that colloidal milling of VO₂ followed by probe sonication was most effective in providing low particle sizes. This processing route allows for the stabilization of cluster sizes under 300 nm for weeks to months. The viscosity can be tuned over several orders of magnitude using both aqueous and non-aqueous inks (FIG. 6). Rheological behavior can be either Newtonian or shear-thinning. Inks with viscosities less than 1 Pas (1000 cP) are required to be compatible with aerosol jet printing. Inks with the compositions outlined in this disclosure have viscosities in the range of 0.3 mPa S to 1 Pas.

The semiconducting nanoparticles can be formed of any electronically semiconducting or electronically correlated material. For example, the nanoparticles can be formed of VO₂ and/or NiO.

The semiconducting nanoparticles can be present in the ink composition in an amount of at least about 50%, for example, about 10% to about 20% by weight based on the total weight of the ink composition. Other suitable amounts include, based on the weight of the total weight of the ink composition, about 10, 11, 12, 13, 14, 15, 16, 17, 18, 19 or 20 wt %, or any values therebetween or ranges defined by such values. Embodiments of the ink can include semiconducting nanoparticle amounts less than 10 wt % based on the total weight of the ink composition, with a stabilizing polymer amount of no more than 20 wt % based on the weight of the nanoparticles. It is believed that in such embodiments, additional printing passes may be needed for printing conductive films by aerosol spray jet printing. As well as certain post-printing annealing treatments, such as rapid photo annealing

The stabilizing polymer is a polymer having organic functional groups and is crosslinkable by the crosslinker. The stabilizing polymer and solvent are selected such that the stabilizing polymer is capable of being dissolved in the solvent. The composition can include the stabilizing polymer in an amount of about 5 wt % to about 60 wt % based on the total weight of the nanoparticles. The stabilizing polymer can include polar functional groups, ionizable groups, and/or groups with large steric interactions. Examples of stabilizing polymers include, but are not limited to, one or more of poly(ethylene-co-methyl methacrylate-co-glycidyl methacrylate) (PEMAGMA), gum arabic, branched PEI, and SMA.

The crosslinker can include one or more of polyols, polyethylene glycol (PEG), Polypropylene glycol (PPG), Poloxamer PEO-PPO-PEO, Polyetheramines, di-polyamines, tri-polyamines, multi-functional epoxies multifunctional bis[2-(methacryloyloxy)ethyl] phosphate (b2mp), PEG diacrylates, PEG dimethacrylates, multifunctional acrylates, and multifunctional methacrylates, multifunctional cyclic carbonates, and triethanolamine. polyethylene glycol, bis[2-methacryloyloxy)ethyl]phosphate, glyoxal. Commercially available crosslinkers include, for example, JEFFAMINE® Polyetheramines, multi-functional epoxies (e.g., Nagase DENACOL™. Selection of a suitable crosslinker for a selected stabilizing polymer can be made by the skilled person based on knowledge in the art. For example, the crosslinker for crosslinking SMA can be polyols, polyethylene glycol (PEG), Polypropylene glycol (PPG), Poloxamer PEO-PPO-PEO, Polyetheramines, di-polyamines, tri-polyamines, multi-functional epoxies (Nagase DENACOL™). Crosslinkers for PEI can include one or more of bis[2-(methacryloyloxy)ethyl]phosphate (b2mp), PEG diacrylates, PEG dimethacrylates, multifunctional acrylates, multifunctional methacrylates, Nagase VEEA and VEEM, and multifunctional cyclic carbonates.

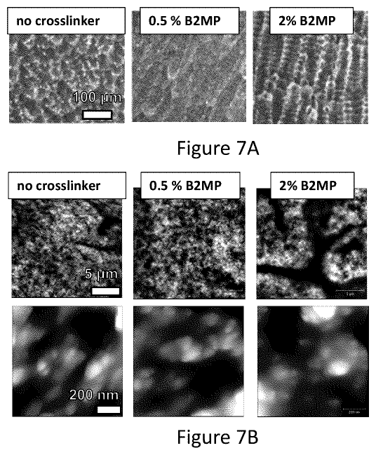

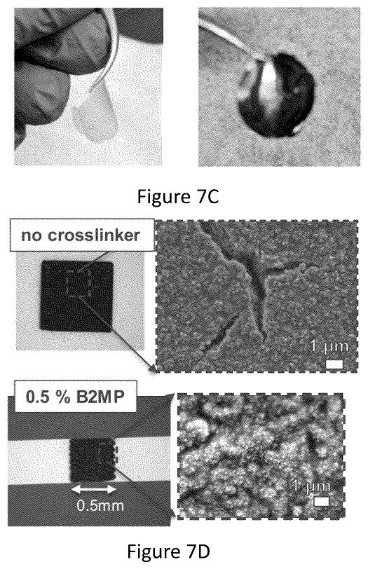

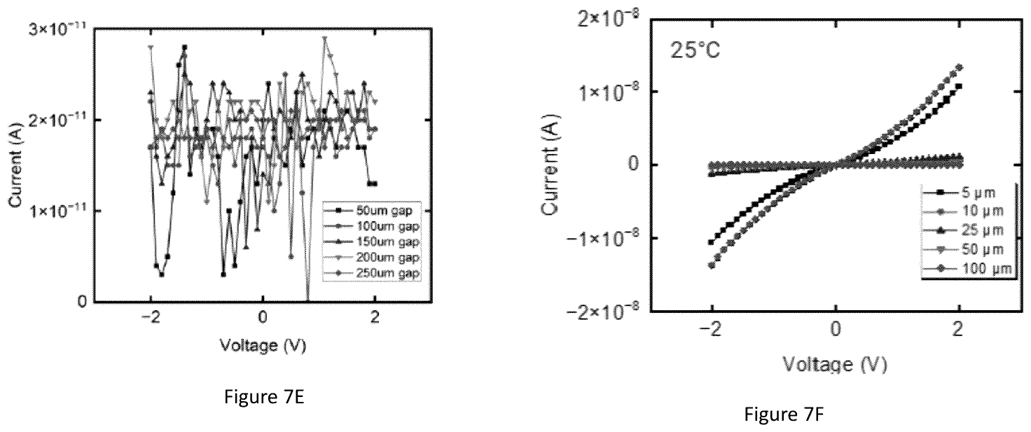

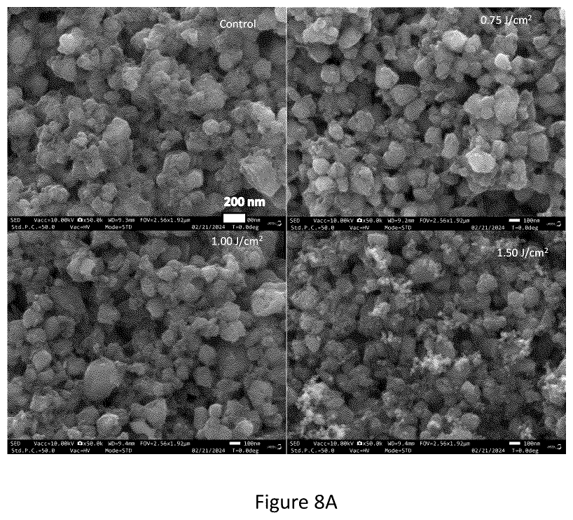

The crosslinker can be present in an amount of about 5 wt % to about 50 wt %, or about 5 wt % to 20 wt %, based on the total weight of the ink composition. Referring to FIG. 7, it was observed that the crosslinker alters the microscale morphology of the deposited films while leaving the nanoscale morphology relatively unaffected. The films in FIG. 7 include B2MP (shown in FIG. 4) as the crosslinker and then thermally crosslinked after depositions. In FIG. 7C it is demonstrated how the crosslinking is robust enough to produce freestanding crosslinked films. Control over microscale morphology allows for the prevention of microscale cracking (FIG. 7D). Preventing such cracks can transform an insulating composite (FIG. 7E) to one with a measurable conductivity (FIG. 7F).

The solvent system can be any suitable solvent for dissolving the stabilizing polymer. The solvent system includes a high boiling point solvent and a low boiling point solvent. High boiling point solvents have a boiling point of at least about 125° C., and low boiling point solvents have a boiling point of 100° C. or less. The high boiling point solvent can include, for example, glycerol, p-xylene, n-butyl acetate, terpineol, ethylene glycol, diethylene glycol, propylene glycol, NMP, DMSO, xylene, p-cymene, isophorone, Cyrene, menthol, menthanol, eucalyptol, EC. The low boiling point solvent can include, for example, water, tetrahydrofuran, ethanol, methyl ether ketone, acetone, MIBK, diethyl ketone, cyclohexane, n-butyl acetate, and ethyl lactate. Commercially available low boiling point solvents can include VertecBio™ ELSOL® KTR1, VertecBio™ ELSOL® KTR2, VertecBio™ EL. The commercially available low boiling point solvents can be used alone or in combination with any of the low boiling point solvents listed herein. For example, the solvent system can include water and glycerol or ethanol and terpineol or methyl ether ketone and terpineol. For example, the solvent system can include a 9:1 ratio of methyl ethyl ketone (MEK) to terpineol.

The solvent system can include about 85 wt % to about 95 wt %, about 85 wt % to about 90 wt %, about 87 wt % to about 93 wt %, or about 90 wt % to about 95 wt % of the low boiling point solvent based on the total weight of the solvent system. Other suitable amounts include, based on the total weight of the solvent system, for example, about 85, 86, 87, 88, 89, 90, 91, 92, 93, 94, or 95 wt %, or any value therebetween or ranges defined by the values.

The solvent system can include about 5 wt % to about 15 wt %, about 10 wt % to about 14 wt %, about 7 wt % to about 11 wt %, or about 5 wt % to about 10 wt %, of the high boiling point solvent based on the total weight of the solvent system. Other suitable amounts include, based on the total weight of the solvent system, for example, about 5, 6, 7, 8, 9, 10, 11, 12, 13, 14, or 15 wt %, or any values therebetween or any ranges defined by the values.

### Method of Aerosol Spray Jet Printing

The ink for forming a redox gating material or for forming a semiconducting channel material can be printed by aerosol spray jet printing. The method can include depositing the ink onto the substrate using an aerosol spray jet deposition method and inducing crosslinking of the crosslinker, if present, in the deposited ink. Crosslinking can be induced by heat, chemical methods, such as solvent induced crosslinking, or photo-induced crosslinking. Any suitable substrates can be used. Substrates may be rigid and brittle (Si) or flexible and transparent (Kapton). PET can be used as the substrate, for example.

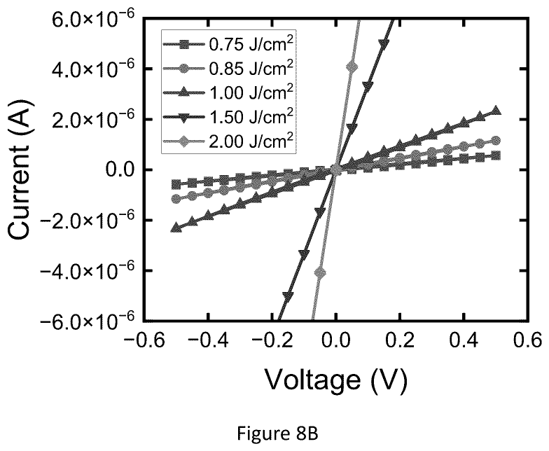

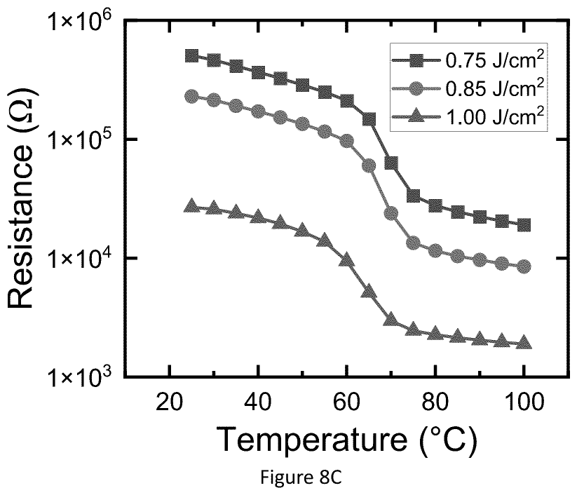

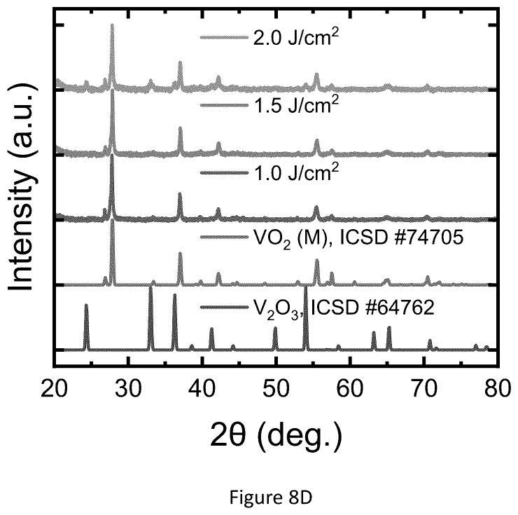

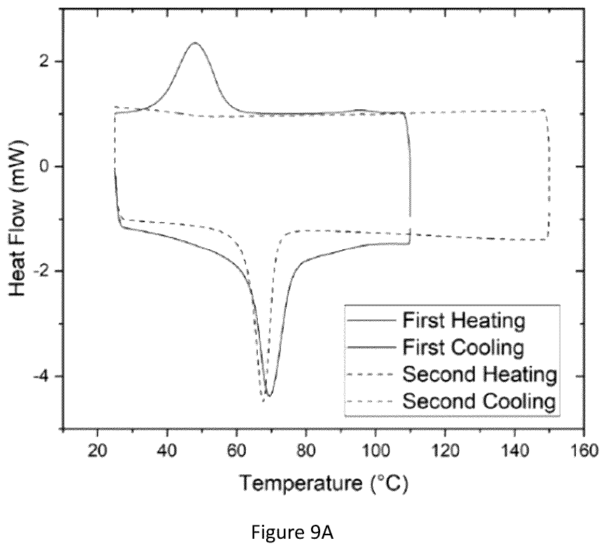

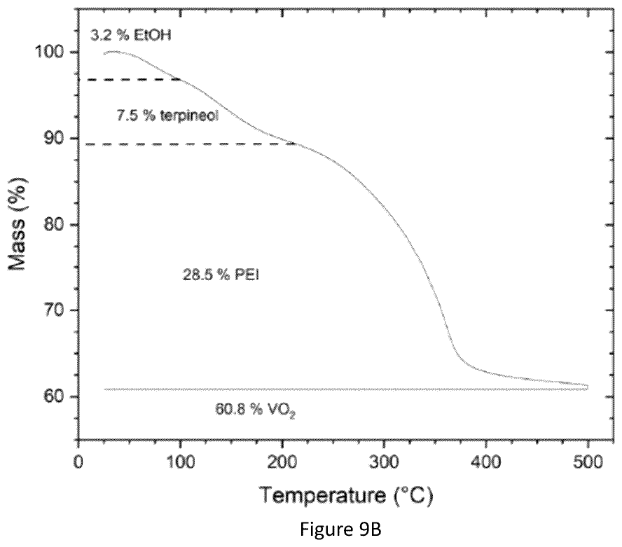

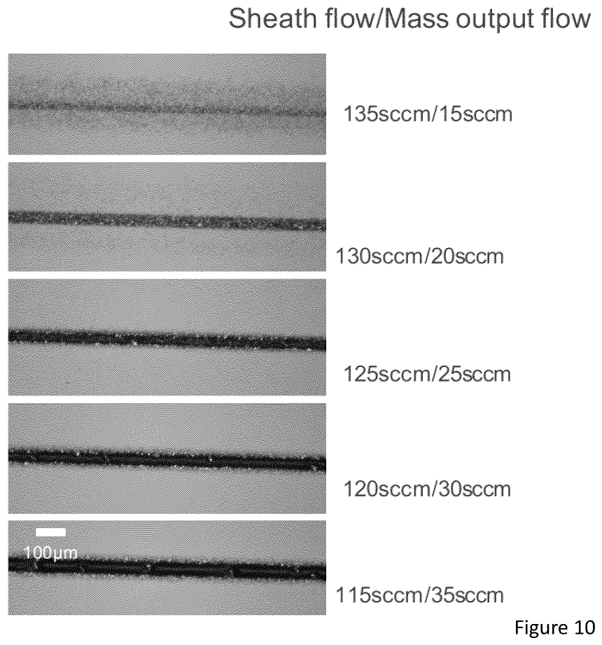

The films can be post-processed after deposition, for example, by annealing. Annealing can be done by thermal, solvent, or pulsed light. Referring to FIG. 8, annealing treatment can be used to control the microstructure and electronic transport properties. As the energy density of the rapid photo annealing treatment is increased, electron microscopy shows how the insulating polymer shells surrounding the nanoparticles can be selectively eliminated to a controlled extent. An insulating channel material can thus experience several orders magnitude increase in conductivity after being treated at 0.75 J/cm². At the same time, XRD shows energy densities up to 2 J/cm² can be reliably used without any changes to the structure and phase state of the metal oxide nanoparticle. Resistance measurements support this by showing the typical metal-to-insulator transition around 65° C. Thermal annealing can be performed at temperature of 110° C. or less (under ambient conditions to avoid thermal oxidation, FIG. 9A) or 200° C. (under inert atmosphere, to avoid thermal degradation, FIG. 9B). Photo-annealing can be performed using 2 J/cm² or less.

A method of forming an electronic device can include depositing a semiconducting ink of the disclosure onto a substrate having electrodes using aerosol spray jet printing to form a semiconducting channel between the electrodes. The electrodes may be sputtered or also printed using aerosol jet printing or similar additive manufacturing methods. The method then includes crosslinking the crosslinker in the deposited semiconducting channel. The method then further includes depositing a redox gating material ink in accordance with the disclosure onto the semiconducting channel using aerosol spray jet printing. If a crosslinking agent is present in the redox gating material ink, the method can further include inducing crosslinking of the crosslinker in the deposited redox gating materials. The method can also further include annealing the as-deposited films, either between deposition of the channel and redox gating materials or after deposition of both the channel and redox gating materials. To complete the device, the final gate electrode may be sputtered, printed, or otherwise deposited onto the gating material.

In the aerosol spray jet printing methods of the disclosure, the redox gating ink and/or the semiconducting ink can be printed using a sheath flow rate of about 100 sccm to about 140 sccm, about 115 sccm to about 135 sccm, or about 120 sccm to about 140 sccm. Other suitable flow rates include about 100, 105, 110, 115, 120, 125, 130, 135, or 140 sccm, or any values therebetween or any ranges defined by the values. The redox gating ink and/or the semiconducting ink can be printed using a mass output flow of about 10 sccm to about 40 sccm, about 15 sccm to about 30 sccm, or about 10 sccm to about 25 sccm. Other mass flow rates include about 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, or 40 sccm, or any values therebetween or any ranges defined by the values.

The ratio of sheath to aerosol flow can be adjusted to achieve a desired resolution. A ratio of the sheath flow rate to the mass output flow can be about 4:1 to about 8:1 or 4:1 to 6:1. FIG. 9 illustrates resolutions for various lines printed at different sheath: mass flow rate. The lower the ratio, the thicker and more uniform the printed lines were observed to be. At ratios below the claimed range, the aerosol stream is not sufficiently focused, creating broader lines with less resolution. The prints in this case are wetter, and dissolved species can diffuse to a greater extent during drying, leading to inhomogeneities within the printed line. Spreading of wet droplets complicates the fabrication of complex, layered devices and can lead to longer and more complicated processing/annealing steps. At high ratios, the lines were thinner, but there was more observed non-uniform scattering of aerosol droplets from overspray effect. Higher ratios above the claimed range can cause clogging of the printing nozzle.

### Examples

### Materials

Methyl ethyl ketone (MEK, also 2-butanone), terpineol, potassium hexacyanoferrate (II) trihydrate, poly(vinyl alcohol) (M_{w}˜30,000), and polyethylene glycol 400, were purchased from Sigma-Aldrich. Ethanol is purchased from Fisher Chemical. Glycerol is purchased from Acros Organics. 1-Ethyl-3-methylimidazolium dicyanide (EMIM-DCA) is purchased from Ionic Liquids Technologies and Sigma-Aldrich. Gum Arabic was purchased from Thermo Fisher Scientific. 8.8 M glyoxal is purchased from TCI Chemicals. Vanadium oxide nanoparticles were purchased from Nanostructured & Amorphous Materials Inc. Scripset® 520 copolymer resins (M_{w}˜350,000 with a 1:1 styrene: maleic anhydride monomer ratio), designated as SMA, were provided by Solenis LLC. Lupasol® WF, a branched, water-free, medium-molecular weight polyethyleneimine (PEI) polymer with a molecular weight of 25,000 g/mol, was provided by BASF—ChemPoint.

### Redox Ink Preparation

A 3% PVOH stock solution was prepared by first mixing the polymer in water at room temperature and heating to 80° C. and stirring for 2 hours to form a clear solution. The polymer solution was stirred overnight at room temperature. Then, the PVOH solution was mixed with PFC redox salt and glyoxal to form the redox ink with a final composition of 1.5 wt % PVOH, 3.33 wt % PFC, and 0.15 wt % glyoxal in the 95:5 H₂O: glycerol cosolvent (solvent system).

### Channel Ink Preparation

The as-purchased particles had a nominal size of 100-200 nm and the powder contained several larger microparticles that compromise ink stability. To improve the dispersion quality and avoid potential printer-clogging issues, the size of the nanoparticles was further reduced, and the size dispersion narrowed by mechanically grinding a concentrated colloidal solution of the VO₂ in ethanol using a planetary ball mill PM400 (Retsch GmbH). In 500 mL grinding jars, the 50% nanoparticle colloidal solution was combined with 0.3 mm Zr beads at a VO₂: Zr mass ratio of 1:4. The milling procedure included 3 minutes at a turntable RPM of 200 (total jar mixture RPM of 600) followed by 15 minutes rest to avoid overheating the particles and causing any undesirable phase changes. The direction of rotation was reversed for each milling repetition. The total processing time was 10 hours including resting time. After the milling completes, the VO₂ nanoparticles are separated from the Zr beads by sifting the grinding jar mixture through a micro sieve. Any remaining ethanol is then evaporated under a chemical hood overnight and the nanoscale powder is then further dried overnight in a vacuum oven.

SMA used for nanoparticle stabilization were first prepared by dissolving the polymer in its appropriate solvent and stirring for at least 24 h. The milled nanoparticles, polymer solution, and solvent mixture were then combined at various ratios and mixed vigorously. Each of the printing inks generally contained 5-10% of a solvent with low volatility such as terpineol or glycerol to prevent premature droplet evaporation during the aerosol atomization and deposition of the printing process. For example, one composition used was 10% milled VO₂ and 0.5% SMA in a 9:1 MEK: terpineol cosolvent.

The mixtures were thoroughly mixed and then probe sonicated using a Fisherbrand sonic dismembrator. One cycle consists of 2.5 min of sonication followed by 7.5 min of rest to avoid sample overheating and excessive evaporation. The inks were thus processed for a total combined sonication time of 2 h, and evaporated solvent was replaced in the final cycle to preserve ink composition. Finally, a small amount of crosslinker was added (10-20% of the polymer mass) to the final ink immediately before printing.

### Channel Ink Characterization

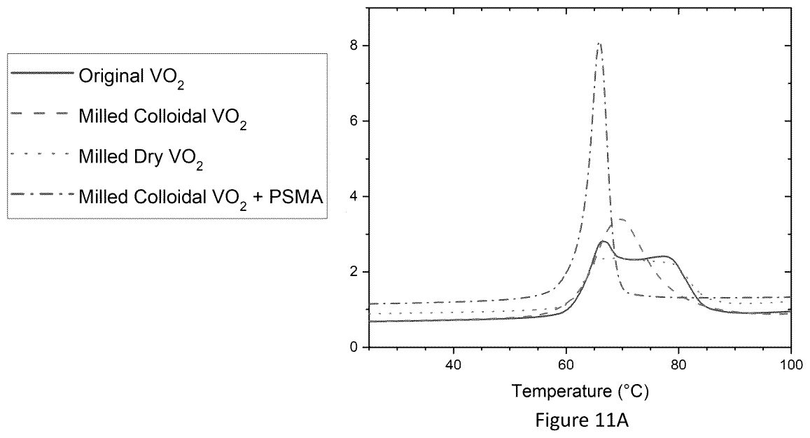

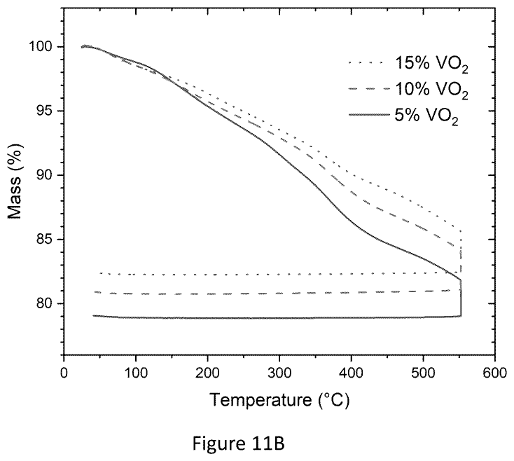

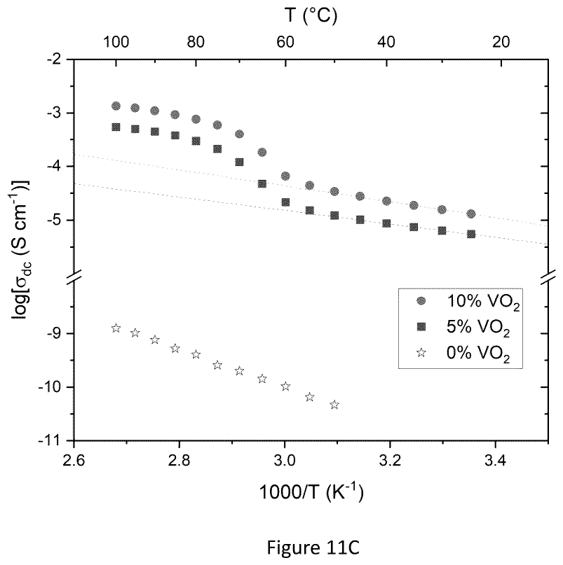

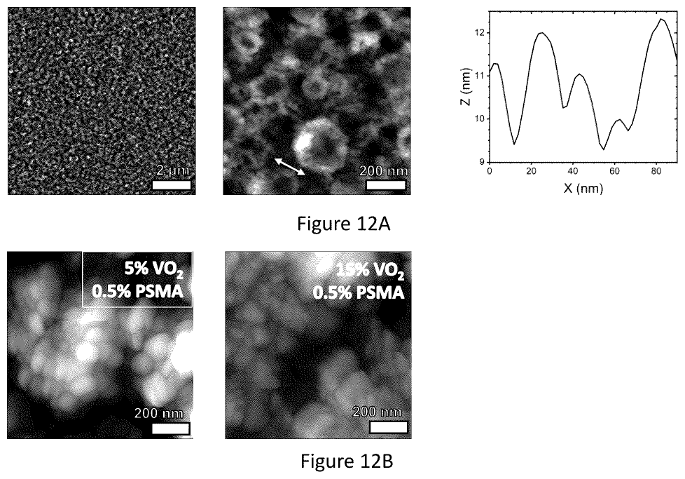

The aggregation behavior of nanoparticle ink suspensions was monitored using a Malvern ZetaSizer Nano. After the final probe sonication step of the ink preparation, inks were then diluted to 0.5 wt % VO₂ concentration, shaken vigorously, placed in a cuvette, and the size dispersions are monitored by dynamic light scattering (FIG. 5). The results demonstrate how selecting the appropriate processing route is critical for controlling the solution self-assembly behavior of the nanoparticles in the ink mixture. For example, milling the nanoparticles as a dry powder produces a highly non-uniform size dispersion of larger nanoparticles and their clusters well above 400 nm in size—even in the presence of a stabilizing polymer (FIG. 5B). On the other hand, smaller aggregates around 200 nm in size are achieved by colloidal milling in ethanol due to the more uniform colloidal environment. The dispersion is further narrowed to this scale by incorporating SMA as a polymer stabilizer, which can adequately disperse the nanoparticles to an appropriate cluster assembly size in the solution for up to 15% VO₂ loading (FIG. 5C). Not only is it critical to achieve narrow nanoparticle aggregate dispersions below 300 nm for the ink to be compatible with aerosol spray jet printing but controlling this assembly behavior via processing route can also be leveraged towards the uniform expression of physical properties in the deposited ink. For example, when VO₂ is cooled from its metallic state at high temperatures to its insulating state at room temperature, it undergoes a phase change from rutile to monoclinic crystal structure which manifests as an exothermic peak in a DSC thermogram (FIG. 11A). For inks with poor, polydisperse aggregate dispersions, this peak is broad due to the kinetic disparity between aggregates of different sizes. This is particularly evident in the unprocessed VO₂ nanoparticles which exhibit a double peak corresponding to a bimodal distribution of nano and microscale aggregates. On the other hand, the most controlled, narrow dispersion achieved by the process outlined above with colloidally milled VO₂ in the presence of SMA produces a single, sharp phase transition which is ideal for electronic switching applications. This processing control via high energy ball milling can be applied to any general metal oxide nanoparticle in which tuning particle size can adjust the physical properties.

The flow curves were collected using a Discovery HR-2 rheometer (TA Instruments) with a steel cone and plate geometry of 40 mm diameter and 59 μm truncation gap. Inks were first conditioned at a 5 s⁻¹ constant shear rate for 5 minutes before the measurement. Referring to FIGS. 6A and 6B, the viscosity was then measured from 0.1 to 1000 s⁻¹. A series of decreasing frequencies in the same range is subsequently measured to examine hysteresis. A wide range of rheological behavior is observed depending on the selection of polymer, nanoparticle, and so-solvent components as well as their relative ratios. For example, in the case of aqueous systems, percolating hydrogen bonding networks arising from water molecules and their interaction with polar nanoparticle systems results in a highly viscous, shear-thinning inks. In this case, viscosity can be tuned by more than 4 orders of magnitude depending on the VO₂ loading fraction and shear rate. In contrast, when less polar solvents such as ethanol are used, viscosities on the order of 1 cP (1 mPa s) are observed, which is relatively independent of nanoparticle loading fraction and shear rate. Hence, judicious selection of the various channel ink components can allow for diverse Newtonian and shear-thinning behavior with tunable viscosity, all of which is compatible with the specifications of aerosol spray jet printing. In combination with printing parameters that deposit large, wet aerosol droplets, tunable rheology allows for a variety of wetting and surface-assembly mechanisms for achieving the ideal film morphology and properties.

The differential scanning calorimetry thermograms were measured using a Mettler Toledo DSC 823 (FIGS. 9 and 11). Samples were prepared by drying drop-cast inks, drying the solid overnight in a vacuum oven, and adding the resulting solid composite to aluminum crucibles. The crucible was cycled first to 110° C. and back to 25° C. before cycling once more to 150° C. and back to 25° C. Measurements are performed both in ambient and inert nitrogen atmospheres. The ramp rate is 10° C./min. The DSC signatures show that the traditional MIT phase transition of VO₂ is preserved in our ink preparation and is moreover tuned by controlling the processing route (FIG. 11). DSC also identifies an upper temperature limit of 110° C. in ambient conditions above which thermal oxidation eliminates the switching behavior of the nanoparticles (FIG. 9). Annealing under inert nitrogen atmosphere avoids such issues.

The final solid composite composition and thermal stability was assessed using a Mettler Toledo TGA 851, using the same sample preparation as in DSC studies (FIGS. 9 and 11). The temperature was increased to 550° C. at a rate of 10° C./min in an inert nitrogen atmosphere. A subsequent cooling curve back to room temperature at the same rate is used to correct the buoyancy effect. Final deposited film compositions can range from around 60 to 84% VO₂ by mass. The final compositions match those expected by the nominal concentrations in the ink, demonstrating the precision and control of the ink formulation and processing. Depending on the polymer used such films can be annealed up to 180 to 200° C. before thermal decomposition will become a concern.

### Redox Ink Preparation

The polymer-based redox ink is a mixture of polyvinyl alcohol (PVOH or PVA) and ferrocyanide dissolved in water: glycerol mixed solvents. The ratio of dual solvent system water/glycerol is optimized as of 95:5 v/v for its good stability for AEROSOL SPRAY JET PRINTING ultrasonic atomization. Water is chosen as the main solvent because it offers high solubility of PVOH and ferrocyanide while glycerol improves the aerosol droplet formation, minimizing overspray effects and enhancing printed feature resolution (FIG. 3). The printed single layer redox material has a thickness of around 10 μm. For a better conductivity of the printed redox material, 3 layers of prints were utilized in the transistor fabrication.

### Film Printing and Post-Deposition Processing

Films were deposited both on Si and flexible Kapton substrates. The Si surfaces were cleaned by 15 minutes of mild sonication in water, acetone, and IPA. A native oxide layer of 1-2 nm was measured on the clean Si using spectroscopic ellipsometry.

To initially check film-formability and the nanoscale ink morphology, inks were spin-coated onto the cleaned Si substrates at 3500 rpm for 1.5 min. Topography images of spin-coated films were recorded on a Bruker Veeco Multimode 8 Ambient AFM using SCANASYST-AIR cantilevers that consist of a silicon tip on nitride lever (spring constant of 0.4 N/m). A percolating network of semiconducting nanoparticles with soft SMA shells is observed at the nanoscale (FIG. 12). Increasing the VO₂ loading produces a denser network with thinner polymer shells. To the extent that SMA is electrically insulating, such polymer shells will result in interparticle charge transfer resistance that limits long range conductivity. Further tailoring the morphology and conductivity of printed nanocomposites to be suitable for microelectronic applications can be achieved through post-deposition treatments, such as thermal crosslinking or rapid photo annealing (RPA).

### Printing Parameters

The SiO₂ (300 nm)/Si substrates underwent sonication in acetone and isopropanol (IPA) for 3 minutes, followed by rinsing with IPA and blow-drying. Subsequently, the substrates were heated at 140° C. for 1 hour to ensure complete drying before printing. The printing of VO₂ films was carried out using an Optomec Aerosol Jet 5X system with a pneumatic atomizer featuring a 300 μm nozzle. Printing parameters were optimized to minimize overspray and ensure uniform film deposition. The parameters were set as follows: sheath flow rate at 120 sccm, atomizer flow rate at 550 sccm, carrier gas flow rate at 30 sccm, printing speed at 10 mm/s, and ink and platen temperature at 23° C. Printed films were annealed at 80° C. for 1 hour to evaporate the solvent and induce crosslinking of the binding polymers. Subsequently, VO₂ films underwent photonic annealing using a PulseForge 1300 system with a radiant energy of 0.75-2 J/cm² to remove polymer residues on the top surface (FIG. 8). Drain and source electrodes were patterned using a shadow mask with e-beam evaporation of Ti (5 nm)/Pt (100 nm), and the channel dimensions were 1000 μm in width and 600 μm in length. The redox ink printing utilized the same aerosol jet printer with an ultrasonic atomizer and a 150 μm nozzle. Printing parameters were set as follows: sheath flow rate at 40 sccm, atomizer flow rate at 20 sccm, printing speed at 4 mm/s, and ink and platen temperature at 23° C. and 50° C., respectively. Printed films were annealed at 80° C. for 0.5 hours to evaporate the solvent and induce polymer crosslinking. All printing and thermal annealing processes were conducted under ambient conditions, while photonic annealing was performed in O₂ to prevent the reduction of VO₂ from decomposed polymer residues.

### Device Printing

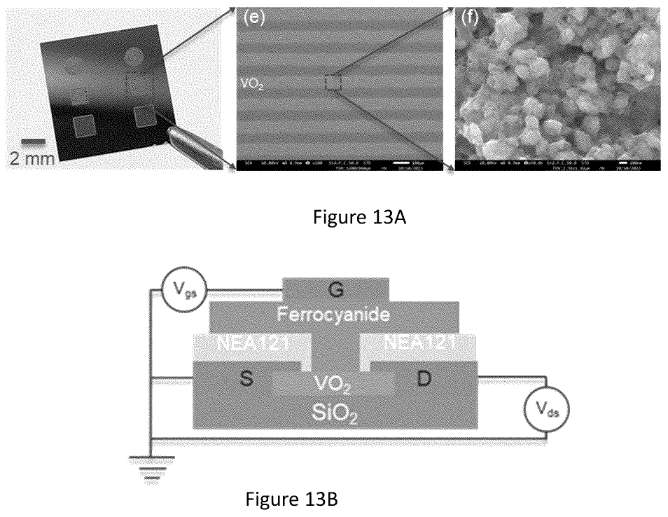

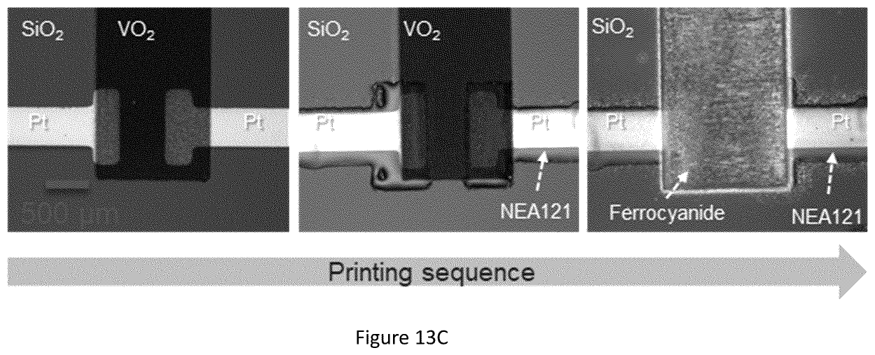

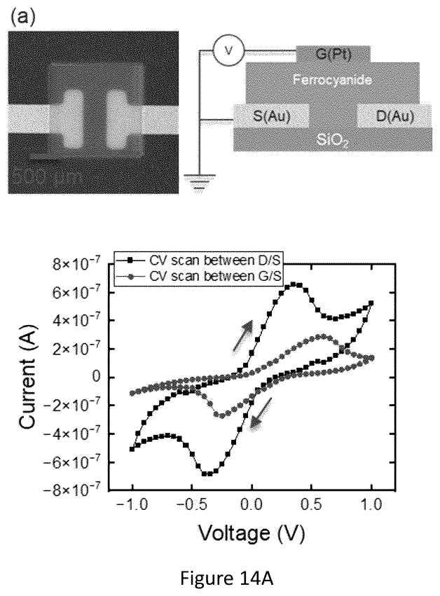

Scanning electron microscope (SEM) images were acquired using a JEOL IT800 instrument. Optimization of the ink formulations and printing parameters allows for the reliable aerosol spray jet printing of redox gating (FIG. 3C) and channel (FIG. 13) inks with high resolution into arbitrary patterns. SEM images a continuous printed VO₂ film composed of an interconnected polymer matrix that densely covered the region. The vertically stacked VO₂ transistor depicted in FIG. 13B, VO₂/Au/NEA121/Redox material, is fabricated layer-by-layer (FIG. 13C): (1) VO₂ ink is printed onto a precleaned Si substrate, forming a VO₂ thin film. (2) E-beam evaporation through a shadow mask deposits Ti/Pt electrodes (drain and source) atop the VO₂ film. (3) A UV-curable dielectric layer, NEA121, is printed on the Pt electrodes to prevent contact with the subsequently printed redox gating materials. Finally, the gate electrode is either sputter-deposited Pt on top of the redox material or a Pt foil in direct contact with it.

Following the printing of VO₂ films, annealing is required to remove the polymer on the surface of VO₂ NPs to ensure good electrical contact with the subsequently e-beam evaporated electrodes. While conventional thermal annealing (>300° C.) risks undesired VO₂ structural changes, photonic annealing has emerged as an efficient alternative for decomposing polymer binders and removing residual solvent in printed materials. Here, we employ intense light pulses to decompose the SMA binder within milliseconds. To preserve the VO₂ NP structure, photonic annealing is performed with a lower energy below 1.5 J/cm², preventing carbon assisted VO₂ reduction. XRD measurements confirm the VO₂ samples retain their crystal structure after photonic annealing, as shown in FIG. 8D.

### Electrical Characterization

All electrical measurements of VO₂ transistors were conducted in ambient conditions using a computer-controlled Keithley 2612B and a micromanipulator probe station. The Keithley instruments were controlled through a LabVIEW interface, enabling automated and systematic data collection.

Photonic annealing tunes the conductivity of VO₂ film by varying the photonic annealing energy density. FIG. 8B presents IV scan results of photonic annealed VO₂ sample with different resistances. The sample configuration features electrodes with 1 mm width and a 600 μm gap, while the printed VO₂ film thickness is approximately 3 μm. The dramatic difference in the resistance stems from the decomposition of SMA on the VO₂ NP surfaces. As shown in FIG. 8A, higher photonic energy of 2.00 J/cm² effectively removes most SMA, exposing bare VO₂ NPs that enhanced electrical connections. Conversely, lower energies leave residual SMA within the matrix, influencing conductivity. The SMA can still be seen within the matrix after photonic annealing with a lower energy of 0.75 J/cm². This tunability provides a significant advantage for printed VO₂ NP applications, allowing tailored conductivity for specific needs.

Since the XRD measurement has confirmed that the photonic annealed printed VO₂ films maintain the desired monoclinic phase with an annealing energy density lower than 1.5 J/cm². We performed IV scans of the VO₂ films on a hot plate with varied temperature from 25° C. to 100° C. (FIG. 8C). The temperature dependence of the measured resistance shows about an order of magnitude decrease in the resistance as the sample is heated above its MIT around 65° C. At temperatures from 80° C. to 100° C., the resistance becomes almost constant at a value. Similar MIT phase transition is observed on VO₂ films annealed at lower photonic energy, albeit with higher resistances. This electrical characterization reveals that printed VO₂ films with photonic annealing treatment exhibit similar MIT characteristics as dry, top-down deposited VO₂ films. It is emphasized that the dry deposited VO₂ films lack the patterning flexibility and compatibility with plastic substrates offered by our aerosol spray jet printing-printed approach.

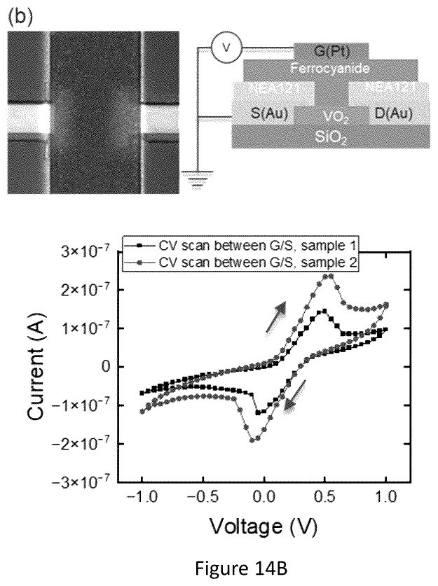

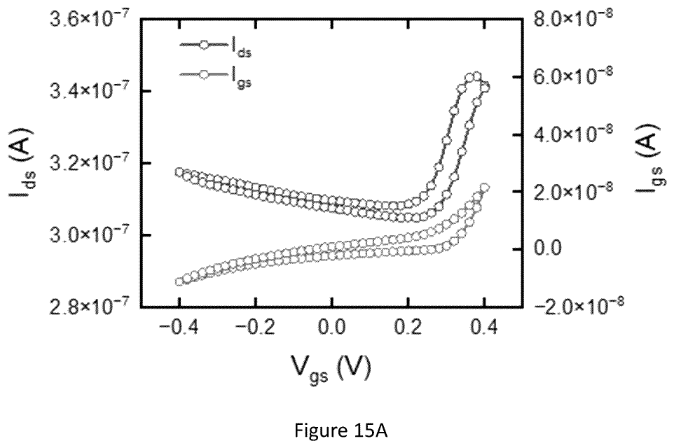

Before the transfer measurement of printed VO₂ transistors, IV scans of the printed redox material are performed to evaluate the redox reactions in the material (FIG. 14). During this IV scans, the positive potential is applied to the top gate electrode (G) which is a Pt foil that directly contacts the surface of redox material. The negative potential is connected to the source electrode(S). The IV scan exhibits a typical cyclic voltammetry characteristic of ferrocyanide, featuring prominent redox reaction peaks at +0.4 V. These results confirm the functioning of redox elements in the solid polymer electrolyte. Subsequently, a similar IV scan is performed on a device which possesses the complete configuration of a VO₂ transistor. While the IV scan reveals a similar redox reaction profile, the redox peaks are shifted to positive side by a voltage of ˜0.3 V. This shift is attributed to the involvement of VO₂ layer in the reaction. Since the S electrode is covered by the polymer dielectric NEA121, the electrical connection between redox material and S electrode must traverse through the VO₂ layer. Because of the charge injection in VO₂ during the redox gating process, the potential requirements for redox reactions are affected, leading to the shifting of peaks. Furthermore, the shift confirms the successful charge injection within the VO₂. It is important to note that charge injection only occurs at positive gating voltages. Although the IV scan shows a reduction occurring at −0.1 V, there is no charge injection at the condition.

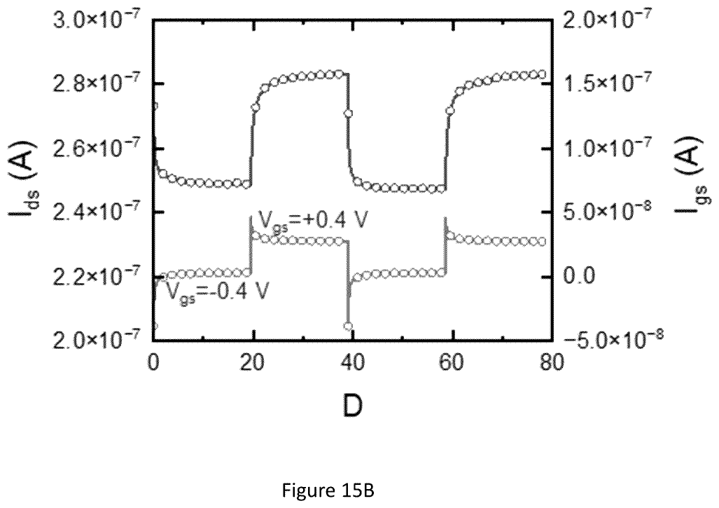

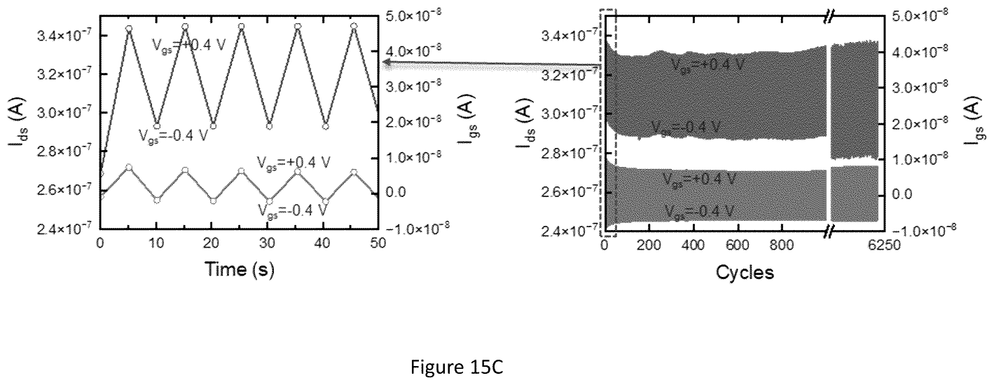

Turning now to the experimental measurement of the transistor, FIG. 15A shows the modulation of the VO₂ conductivity with the gate source voltage (V_{gs}) sweeping. Starting from an insulating state at V_{gs}=−0.4 V, the drain source current (I_{ds}) increases from 3.17×10⁻⁷ A to 3.44×10⁻⁷ A when the V_{gs} reaches 0.4 V. The range of sweep voltage aligns with the measured redox reaction potentials in FIG. 14B, where the charge injection or the oxidation of ferrocyanide occurred at V_{gs}=0.4 V. Further increasing the sweeping voltage higher than 0.4 V will cause las current drop and the device will have a lower las current modulation rate. Following the positive sweeping of V_{gs}, the voltage sweep is reversed from 0.4 V to −0.4 V. The las current returns to its initial value, exhibiting a minimal hysteresis loop. Regarding the gate current (I_{gs}) from redox reactions, only the oxidation peak related to charge injection is observed in the trend and the reduction peak is submerged in the sweep current. This indicates that the charge consumption by VO₂ layers is involved in the charge injection into VO₂ layers and limits the remaining species for further redox reactions. Note that the I_{gs} current from charge injection is more than an order of magnitude lower than the transfer current las, indicating that the observed amplification in las is not due to leakage current in the system. These observations highlight a strong correlation between the redox gating effect and the distinctive conductivity modulation of VO₂ channel material. While the modulation of the VO₂ conductivity is lower than the previously reported epitaxial grown VO₂ transistor with liquid-phase redox gating material, the simply printed VO₂ transistor demonstrates promising potential for practical applications with all solid-state material systems, utilizing low voltage and low power consumption.

To evaluate the cycling performance of the redox gating effect and stability of the redox gated VO₂ transistors, we perform cycling experiments of the same device. FIG. 15D shows the time response of las current of the VO₂ transistor to a square shaped V_{gs} with a pulsed amplitude of ±0.4 V and a switching delay of 19 s. The detailed response reveals that reaching 90% of the maximum las current takes ˜5 s. FIG. 15E demonstrates long-term cycling measurement of the transistor with the same gating voltage and a switching delay of 5 s. The device exhibits excellent reproducibility in its las current response to the repeated I pulses. Notably, long term cycling measurement shows that the device can operate for more than 6000 cycles without any decay.

The foregoing description is given for clearness of understanding only, and no unnecessary limitations should be understood therefrom, as modifications within the scope of the disclosure may be apparent to those having ordinary skill in the art.

All patents, patent applications, government publications, government regulations, and literature references cited in this specification are hereby incorporated herein by reference in their entirety. In the case of conflict, the present description, including definitions, will control.

Throughout the specification, where the compounds, compositions, methods, and/or processes are described as including components, steps, or materials, it is contemplated that the compounds, compositions, methods, and/or processes can also comprise, consist essentially of, or consist of any combination of the recited components or materials, unless described otherwise. Component concentrations can be expressed in terms of weight concentrations, unless specifically indicated otherwise. Combinations of components are contemplated to include homogeneous and/or heterogeneous mixtures, as would be understood by a person of ordinary skill in the art in view of the foregoing disclosure.

### Aspects of the Disclosure

Aspect 1. An aerosol spray printable ink composition for printing a redox gating material, comprising:
one or more redox agents, the one or more redox agents comprising a transition metal salt with variable valency and/or a polymer with at least one redox-active functional group; and
a solvent system comprising, based on the total weight of the solvent system, about 85 wt % to 95 wt % of a low boiling point solvent and about 5 wt % to about 15 wt % of a high boiling point solvent, wherein the low boiling point solvent has a boiling point below about 100° C. and the high boiling point solvent has a boiling point above about 125° C.,
wherein the redox agent is present in the composition in an amount of about 3 wt % to about 10 wt % based on the total weight of the ink composition.

Aspect 2. The composition of aspect 1, wherein the one or more redox agent comprises one or more transition metal salt with variable valency selected from the group consisting of Cu ions, Fe ions, V ions, Co ions, Ni ions, their corresponding coordination ions, or combinations thereof.

Aspect 3. The composition of aspect 2, wherein the transition metal salt is present in an amount below the saturation concentration in the solvent system.

Aspect 4. The composition of aspect 1, wherein the one or more redox agent comprises the polymer with at least one redox active functional group and at least one crosslinkable group, and the composition further comprises a crosslinker, wherein the ink composition is for printing a solid state redox gating material.

Aspect 5. The composition of aspect 4, wherein the crosslinker comprises one or more of polyols, polyethylene glycol (PEG), Polypropylene glycol (PPG), Poloxamer PEO-PPO-PEO, Polyetheramines, di-polyamines, tri-polyamines, multi-functional epoxies multifunctional bis[2-(methacryloyloxy)ethyl]phosphate (b2mp), PEG diacrylates, PEG dimethacrylates, multifunctional acrylates, and multifunctional methacrylates, multifunctional cyclic carbonates, triethanolamine. polyethylene glycol, bis[2-methacryloyloxy)ethyl]phosphate, and glyoxal.

Aspect 6. The composition of aspect 1, wherein the redox agent comprises the polymer with at least one redox active functional group.

Aspect 7. The composition of any one of aspects 1 or 4 to 6, wherein the one or more redox-active functional group is selected from the group consisting of ferrocene, viologen, quinone, TEMPO, thiophene, benzophenone, ferrocyanide, ferricyanide, and combinations thereof.

Aspect 8. The composition of any one of aspects 1 or 4 to 7, wherein the redox agent comprises one or more of poly(ionic liquids) comprising the one or more redox-active functional groups and ionic liquid species in monomer repeating units, connected through a polymeric backbone to form a macromolecular architecture.

Aspect 9. The composition of aspect 8, wherein the poly(ionic liquid) is present in the composition in an amount of about 1 wt % to about 15 wt % based on the total weight of the ink composition.

Aspect 10. The composition of aspect 8 or 9, wherein the ionic liquid species comprises one or more of quaternary imidazolines, imidazoliums, quaternary pyridines, ferrocenium, cobaltocenium, ferrocyanide, ferrocyanide, dicyanamide, bis(trifluoromethylsulfonyl)imide, and hexafluorophosphate.

Aspect 11. The composition of any one of aspects 8 to 10, wherein the one or more poly(ionic liquid) comprises one or both of a conjugated poly(ionic liquid) and a metal-containing poly(ionic liquid).

Aspect 12. The composition of aspect 11, wherein the conjugated poly(ionic liquid) comprises one or more of polythiophene poly(ionic liquid), poly(quinone) poly(ionic liquid), and poly(viologen) poly(ionic liquid).

Aspect 13. The composition of aspect 12, wherein the polythiophene poly(ionic liquid) comprises one or both of 3,4-ethylenedioxythiophene and imidazole-functionalized thiophene monomers.

Aspect 14. The composition of aspect 13, wherein the poly(quinone) poly(ionic liquid) comprises repeating quinone isomers.

Aspect 15. The composition of aspect 14, wherein the repeating quinone isomers comprises one or more of benzoquinones, naphthoquinones, anthraquinone, and phenanthraquinones.

Aspect 16. The composition of aspect 12, wherein the poly(viologen) poly(ionic liquid) comprises one or both of conjugated bi-/multi-pyridyl groups and 1,1′-disubstituted-4,4′-bipyridiliums.

Aspect 17. The composition of any one of aspects 11 to 16, wherein the metal-containing poly(ionic liquid) comprises one or more of ferrocene-containing poly(ionic liquids), ferrocyanide-containing poly(ionic liquids), and ferricyanide-containing poly(ionic liquids).

Aspect 18. The composition of aspect 17, wherein ferrocene-containing poly(ionic liquids) comprises one or more of ferrocenylenes, ferrocenylsilanes, and pendant ferrocenes.

Aspect 19. The composition of any one of the preceding aspects, further comprising a film former and a gelation agent, wherein the ink composition is for printing a solid state redox gating material.

Aspect 20. The composition of aspect 19, wherein:
the film former comprises polyvinyl alcohol (PVOH or PVA), and/or polyethyleneimine (PEI), and
the gelation agent comprises one or more of polyols, polyethylene glycol (PEG), Polypropylene glycol (PPG), Poloxamer PEO-PPO-PEO, Polyetheramines, di-polyamines, tri-polyamines, multi-functional epoxies multifunctional bis[2-(methacryloyloxy)ethyl]phosphate (b2mp), PEG diacrylates, PEG dimethacrylates, multifunctional acrylates, and multifunctional methacrylates, multifunctional cyclic carbonates, triethanolamine. polyethylene glycol, bis[2-methacryloyloxy)ethyl]phosphate, and glyoxal.

Aspect 21. The composition of any one of the preceding aspects, further comprising a viscosity modifying agent.

Aspect 22. The composition of aspect 21, wherein the viscosity modifying agent comprises one or more of polyvinyl alcohol (PVOH or PVA) and/or polyethyleneimine (PEI).

Aspect 23. The composition of aspect any one of the preceding aspects, further comprising an electrolyte.

Aspect 24. The composition of aspect 23, wherein the electrolyte is an ionic liquid.

Aspect 25. The composition of aspect 23, wherein the electrolyte is one or more of 1-ethyl-3-methylimidazolium dicyanamide (EMIM-DCA), DEME-TFSI, EMIM-TFSI, and 1-Butyl-3-methylimidazolium dicyanamide (BMIM-DCA).

Aspect 26. The composition of any one of the preceding aspects wherein the high boiling point solvent comprises one or more of glycerol, terpineol, ethylene glycol, diethylene glycol, propylene glycol, N-methylpyrrolidone (NMP), dimethyl sulfoxide (DMSO), xylene, p-cymene, isophorone, cyrene, menthol, menthanol, eucalyptol, and ethylene carbonate (EC).

Aspect 27. The composition of any one of the preceding aspects, wherein the low boiling point solvent comprises one or more of water, tetrahydrofuran, ethanol, methyl ethyl ketone (MEK), acetone, methyl isobutyl ketone (MIBK), diethyl ketone, cyclohexane, n-butyl acetate, ethyl lactate.

Aspect 28. The composition of any one of the preceding aspects, wherein the solvent system comprises water and glycerol.

Aspect 29. A semiconducting aerosol spray printable ink composition for printing a channel material, comprising:
semiconducting nanoparticles present in an amount up to about 20 wt %, the semiconducting nanoparticles having an average particle size of 100 nm or less;
a solvent system comprising, based on the total weight of the solvent system, about 85 wt % to 95 wt % of a low boiling point solvent and about 5 wt % to about 15 wt % of a high boiling point solvent, wherein the low boiling point solvent has a boiling point below about 100° C. and the high boiling point solvent has a boiling point above about 125° C.;
a stabilizing polymer present in an amount of at least about 5 wt % based on the weight of the nanoparticles, the stabilizing polymer being dissolvable in the solvent; and
a crosslinker.

Aspect 30. The ink composition of aspect 29, wherein the nanoparticles have an average particle size of about 5 nm to about 100 nm.

Aspect 31. The ink composition of aspect 30, wherein the nanoparticles have an average particle size of about 40 nm to about 60 nm.

Aspect 32. The ink composition of any one of aspects 29 to 31, wherein the semiconducting nanoparticles comprise VO₂ or NiO.

Aspect 33. The ink composition of any one of aspects 29 to 32, wherein the nanoparticles are present in an amount of about 5 wt % to about 20 wt %.

Aspect 34. The ink composition of aspect 33, wherein the nanoparticles are present in an amount of about 10 wt % to about 20 wt %.

Aspect 35. The ink composition of any one of aspects 29 to 34, wherein the stabilizing polymer is present in an amount of about 5 wt % to about 60 wt %.

Aspect 36. The ink composition of aspect 35, wherein the stabilizing polymer is present in an amount of about 5 wt % to about 40 wt %.

Aspect 37. The ink composition of any one of aspects 29 to 26, wherein the stabilizing polymer is selected from poly(ethylene-co-methyl methacrylate-co-glycidyl methacrylate), gum arabic, branched poly(ethyleneimine), poly(styrene-co-maleic anhydride).

Aspect 38. The ink composition of any one of aspects 29 to 37, wherein the crosslinker comprises one or more of polyols, polyethylene glycol (PEG), Polypropylene glycol (PPG), Poloxamer PEO-PPO-PEO, Polyetheramines, di-polyamines, tri-polyamines, multi-functional epoxies multifunctional bis[2-(methacryloyloxy)ethyl]phosphate (b2mp), PEG diacrylates, PEG dimethacrylates, multifunctional acrylates, and multifunctional methacrylates, multifunctional cyclic carbonates, triethanolamine. polyethylene glycol, bis[2-methacryloyloxy)ethyl]phosphate, and glyoxal.

Aspect 39. The ink composition of aspect 38, wherein the crosslinker is present in an amount of about 5 wt % to about 50 wt % based on the total weight of the ink composition.

Aspect 40. The ink composition of any one of aspects 29 to 39, wherein the high boiling point solvent comprises one or more of glycerol, terpineol, ethylene glycol, diethylene glycol, propylene glycol, N-methylpyrrolidone (NMP), dimethyl sulfoxide (DMSO), xylene, p-cymene, isophorone, cyrene, menthol, menthanol, eucalyptol, and ethylene carbonate (EC).

Aspect 41. The ink composition of any one of aspects 29 to 40, wherein the low boiling point solvent comprises one or more of water, tetrahydrofuran, ethanol, methyl ethyl ketone (MEK), acetone, methyl isobutyl ketone (MIBK), diethyl ketone, cyclohexane, n-butyl acetate, ethyl lactate.

Aspect 42. The ink composition of aspect 41, wherein the solvent system comprises a 9:1 ratio of methyl ethyl ketone (MEK): terpineol.

Aspect 43. A method of aerosol spray printing an electronic device, comprising:
depositing a semiconducting ink composition onto a substrate comprising electrodes between the electrodes, the semiconducting ink composition being deposited by aerosol spray printing, and the semiconducting ink composition comprising:
   semiconducting nanoparticles present in an amount up to about 20 wt %, the semiconducting nanoparticles having an average particle size of 100 nm or less;
   a solvent system comprising, based on the total weight of the solvent system, about 85 wt % to 95 wt % of a low boiling point solvent and about 5 wt % to about 15 wt % of a high boiling point solvent, wherein the low boiling point solvent has a boiling point below about 100° C. and the high boiling point solvent has a boiling point above about 125° C.;
   a stabilizing polymer present in an amount of at least about 5 wt % based on the weight of the nanoparticles, the stabilizing polymer being dissolvable in the solvent; and
   a crosslinker;
crosslinking the deposited semiconducting ink composition to form the semiconducting channel; and
depositing a redox gating material ink composition onto the semiconducting channel by aerosol spray printing, the redox gating material ink composition comprising:
   one or more redox agents, the one or more redox agents comprising a transition metal salt with variable valency and/or a polymer with at least one redox-active functional group; and
   a solvent system comprising, based on the total weight of the solvent system, about 85 wt % to 95 wt % of a low boiling point solvent and about 5 wt % to about 15 wt % of a high boiling point solvent, wherein the low boiling point solvent has a boiling point below about 100° C. and the high boiling point solvent has a boiling point above about 125° C.,
   wherein the redox agent is present in the composition in an amount of about 3 wt % to about 10 wt % based on the total weight of the ink composition.

Aspect 44. The method of aspect 43, further comprising annealing the deposited semiconducting ink composition by one or more of thermal, solvent, and pulsed light.

Aspect 45. The method of aspect 43 or 44, further comprising annealing the deposited redox gating ink composition by one or more of thermal, solvent, and pulsed light.

What is claimed is:

1. A semiconducting aerosol spray printable ink composition for printing a channel material, comprising:
semiconducting nanoparticles present in an amount up to about 20 wt %, the semiconducting nanoparticles having an average particle size of 100 nm or less;
a solvent system comprising, based on the total weight of the solvent system, about 85 wt % to 95 wt % of a low boiling point solvent and about 5 wt % to about 15 wt % of a high boiling point solvent, wherein the low boiling point solvent has a boiling point below about 100° C. and the high boiling point solvent has a boiling point above about 125° C.;
a stabilizing polymer present in an amount of at least about 5 wt % based on the weight of the nanoparticles, the stabilizing polymer being dissolvable in the solvent; and
a crosslinker.

2. The ink composition of claim 1, wherein the nanoparticles have an average particle size of about 5 nm to about 100 nm.

3. The ink composition of claim 2, wherein the nanoparticles have an average particle size of about 40 nm to about 60 nm.

4. The ink composition of claim 1, wherein the semiconducting nanoparticles comprise VO₂ or NiO.

5. The ink composition of claim 1, wherein the nanoparticles are present in an amount of about 5 wt % to about 20 wt %.

6. The ink composition of claim 5, wherein the nanoparticles are present in an amount of about 10 wt % to about 20 wt %.

7. The ink composition of claim 1, wherein the stabilizing polymer is present in an amount of about 5 wt % to about 60 wt %.

8. The ink composition of claim 7, wherein the stabilizing polymer is present in an amount of about 5 wt % to about 40 wt %.

9. The ink composition of claim 1, wherein the stabilizing polymer is selected from poly(ethylene-co-methyl methacrylate-co-glycidyl methacrylate), gum arabic, branched poly(ethyleneimine), poly(styrene-co-maleic anhydride).

10. The ink composition of claim 1, wherein the crosslinker comprises one or more of polyols, polyethylene glycol (PEG), Polypropylene glycol (PPG), Poloxamer PEO-PPO-PEO, Polyetheramines, di-polyamines, tri-polyamines, multi-functional epoxies multifunctional bis[2-(methacryloyloxy)ethyl]phosphate (b2mp), PEG diacrylates, PEG dimethacrylates, multifunctional acrylates, and multifunctional methacrylates, multifunctional cyclic carbonates, triethanolamine, polyethylene glycol, bis[2-methacryloyloxy)ethyl]phosphate, and glyoxal.

11. The ink composition of claim 10, wherein the crosslinker is present in an amount of about 5 wt % to about 50 wt % based on the total weight of the ink composition.

12. The ink composition of claim 1, wherein the high boiling point solvent comprises one or more of glycerol, terpineol, ethylene glycol, diethylene glycol, propylene glycol, N-methylpyrrolidone (NMP), dimethyl sulfoxide (DMSO), xylene, p-cymene, isophorone, cyrene, menthol, menthanol, eucalyptol, and ethylene carbonate (EC).

13. The ink composition of claim 1, wherein the low boiling point solvent comprises one or more of water, tetrahydrofuran, ethanol, methyl ethyl ketone (MEK), acetone, methyl isobutyl ketone (MIBK), diethyl ketone, cyclohexane, n-butyl acetate, ethyl lactate.

14. The ink composition of claim 13, wherein the solvent system comprises a 9:1 ratio of methyl ethyl ketone (MEK): terpineol.

15. An aerosol spray printable ink composition for printing a redox gating material, comprising:
one or more redox agents, the one or more redox agents comprising a transition metal salt with variable valency and/or a polymer with at least one redox-active functional group; and
a solvent system comprising, based on the total weight of the solvent system, about 85 wt % to 95 wt % of a low boiling point solvent and about 5 wt % to about 15 wt % of a high boiling point solvent, wherein the low boiling point solvent has a boiling point below about 100° C. and the high boiling point solvent has a boiling point above about 125° C.,
wherein the redox agent is present in the composition in an amount of about 3 wt % to about 15 wt % based on the total weight of the ink composition.

16. The composition of claim 15, wherein the one or more redox agent comprises one or more transition metal salt with variable valency selected from the group consisting of Cu ions, Fe ions, V ions, Co ions, Ni ions, their corresponding coordination ions, or combinations thereof.

17. The composition of claim 15, wherein the one or more redox agent comprises the polymer with at least one redox active functional group and at least one crosslinkable group, and the composition further comprises a crosslinker, wherein the ink composition is for printing a solid state redox gating material.

18. The composition of claim 15, wherein the redox agent comprises one or more of poly(ionic liquids) comprising the one or more redox-active functional groups and ionic liquid species in monomer repeating units, connected through a polymeric backbone to form a macromolecular architecture.

19. A method of aerosol spray printing an electronic device, comprising:
depositing a semiconducting ink composition onto a substrate comprising electrodes between the electrodes, the semiconducting ink composition being deposited by aerosol spray printing, and the semiconducting ink composition comprising:
semiconducting nanoparticles present in an amount up to about 20 wt %, the semiconducting nanoparticles having an average particle size of 100 nm or less,
a solvent system comprising, based on the total weight of the solvent system, about 85 wt % to 95 wt % of a low boiling point solvent and about 5 wt % to about 15 wt % of a high boiling point solvent, wherein the low boiling point solvent has a boiling point below about 100° C. and the high boiling point solvent has a boiling point above about 125° C.,
a stabilizing polymer present in an amount of at least about 5 wt % based on the weight of the nanoparticles, the stabilizing polymer being dissolvable in the solvent, and
a crosslinker;
crosslinking the deposited semiconducting ink composition to form the semiconducting channel; and
depositing a redox gating material ink composition onto the semiconducting channel by aerosol spray printing, the redox gating material ink composition comprising:
one or more redox agents, the one or more redox agents comprising a transition metal salt with variable valency and/or a polymer with at least one redox-active functional group, and
a solvent system comprising, based on the total weight of the solvent system, about 85 wt % to 95 wt % of a low boiling point solvent and about 5 wt % to about 15 wt % of a high boiling point solvent, wherein the low boiling point solvent has a boiling point below about 100° C. and the high boiling point solvent has a boiling point above about 125° C.,
wherein the redox agent is present in the composition in an amount of about 3 wt % to about 10 wt % based on the total weight of the ink composition.

20. The method of claim 19, further comprising annealing the deposited semiconducting ink composition and/or the deposited redox gating ink composition by one or more of thermal, solvent, and pulsed light.
